(19) United States
(12) Patent Application Publication
(10) Pub. No.: US 2015/0295092 A1
(43) Pub. Date: Oct. 15, 2015

(54) SEMICONDUCTOR DEVICE

(71) Applicant: SHARP KABUSHIKI KAISHA, Osaka-shi, Osaka (JP)

(72) Inventor: Katsunori Misaki, Yonago-shi (JP)

(73) Assignee: Sharp Kabushiki Kaisha, Osaka-shi, Osaka (JP)

(21) Appl. No.: 14/432,540

(22) PCT Filed: Sep. 19, 2013
(86) PCT No.: PCT/JP2013/075295

§ 371 Date: Mar. 31, 2015

(30) Foreign Application Priority Data
Oct. 1, 2012 (JP) 2012-219664

(51) Int. Cl. H01L 29/786; H01L 29/45; H01L 29/24

(52) U.S. Cl. CPC H01L 29/7869; H01L 29/24; H01L 29/45; H01L 29/78606

(57) ABSTRACT

This semiconductor device (201) includes a thin-film transistor (101) having an oxide semiconductor layer (5), wherein each of a source electrode (7) and a drain electrode (9) of the thin-film transistor (101) includes: a main layer (7a, 9a) containing a first metal; a lower layer (7c, 9c) arranged on the substrate side of the main layer, the lower layer (7c, 9c) including, in this order away from the main layer, a lower metal nitride layer made of a nitride of a second metal and a lower metal layer made of the second metal; and an upper layer (7b, 9b) arranged on the opposite side of the main layer from the substrate, the upper layer (7b, 9b) including, in this order away from the main layer, an upper metal nitride layer made of a nitride of the second metal and an upper metal layer made of the second metal, and wherein the first metal is aluminum or copper and the second metal is titanium or molybdenum.

### TECHNICAL FIELD

The present invention relates to a semiconductor device formed by using an oxide semiconductor.

### BACKGROUND ART

An active-matrix substrate used in a liquid crystal display device, or the like, includes a switching element such as a thin-film transistor (hereinafter referred to as a “TFT”) for each pixel. TFTs using an amorphous silicon film as the active layer (hereinafter referred to as “amorphous silicon TFTs”) and TFTs using a polycrystalline silicon film as the active layer (hereinafter referred to as “polycrystalline silicon TFTs”) have been widely used in the art as such switching elements.

Recently, it has been proposed to use an oxide semiconductor, instead of an amorphous silicon or a polycrystalline silicon, as the material of the active layer of a TFT. Such a TFT is called an “oxide semiconductor TFT”. An oxide semiconductor has higher mobility than an amorphous silicon. Therefore, an oxide semiconductor TFT can operate faster than an amorphous silicon TFT. Moreover, since an oxide semiconductor film is made by a simpler process than a polycrystalline silicon film, it can be applied to those apparatuses that require large areas.

With an oxide semiconductor TFT, if the source and drain electrodes are formed of an aluminum (Al) layer or a copper (Cu) layer, the contact resistance will be high between the Al layer or the Cu layer and the oxide semiconductor layer. In order to solve this problem, it has been disclosed to form a Ti layer between an Al layer or a Cu layer and an oxide semiconductor layer (Patent Document No. 1, for example). Patent Document No. 2 discloses using source and drain electrodes having a structure (Ti/Al/Ti) in which an Al layer is sandwiched between Ti layers.

### CITATION LIST

### Patent Literature

Patent Document No. 1: Japanese Laid-Open Patent Publication No. 2010-123923
Patent Document No. 2: Japanese Laid-Open Patent Publication No. 2010-123748

### SUMMARY OF INVENTION

### Technical Problem

The present inventor conducted a study to discover that where source and drain electrodes of a structure where a Ti layer is formed on the surface of a Cu or Al layer, the resistance of the source and drain electrodes or lines may possibly increase through the heat treatment step to be performed after the formation of the source and drain electrodes. As a result, it may be difficult to realize desirable TFT characteristics. Similar problems arise also when an Mo layer is used instead of a Ti layer. This will later be described in detail.

Embodiments of the present invention have been made in view of the problems set forth above, and an object thereof is to provide an oxide semiconductor TFT including source and drain electrodes having a multilayer structure, in which the increase in the resistance of the source and drain electrodes is suppressed, thereby realizing desirable TFT characteristics.

### Solution to Problem

A semiconductor device according to an embodiment of the present invention includes a substrate, and a thin-film transistor supported on the substrate, wherein: the thin-film transistor includes an oxide semiconductor layer, a gate electrode, a gate insulating layer formed between the gate electrode and the oxide semiconductor layer, and a source electrode and a drain electrode which are in contact with the oxide semiconductor layer; each of the source electrode and the drain electrode includes: a main layer including a first metal; a lower layer arranged on the substrate side of the main layer closer to the substrate, the lower layer including, in this order away from the main layer, a lower metal nitride layer made of a nitride of a second metal and a lower metal layer made of the second metal; and an upper layer arranged on the opposite side of the main layer from the substrate, the upper layer including, in this order away from the main layer, an upper metal nitride layer made of a nitride of the second metal and an upper metal layer made of the second metal; and the first metal is aluminum or copper, and the second metal is titanium or molybdenum.

In one embodiment, the lower metal nitride layer is in contact with a lower surface of the main layer, and the upper metal nitride layer is in contact with an upper surface of the main layer.

In one embodiment, one of the lower metal layer and the upper metal layer is in contact with the oxide semiconductor layer.

In one embodiment, the upper layer or the lower layer of the source electrode and the drain electrode further includes another metal nitride layer made of a nitride of the second metal and arranged so as to be in contact with the oxide semiconductor layer.

In one embodiment, the semiconductor device further includes a first protective layer covering the thin-film transistor, the first protective layer being a silicon oxide film, wherein: the upper layer of the source electrode and the drain electrode further includes another metal nitride layer made of a nitride of the second metal and arranged between the upper metal layer and the first protective layer; and the other metal nitride layer is in contact with the first protective layer.

In one embodiment, the semiconductor device further includes a first protective layer covering the thin-film transistor, the first protective layer being a silicon oxide film, wherein: the gate electrode is arranged between the substrate and the oxide semiconductor layer; the lower layer of the source electrode and the drain electrode further includes a lower metal nitride surface layer made of a nitride of the second metal and arranged between the lower metal layer and the oxide semiconductor layer; the upper layer of the source electrode and the drain electrode further includes an upper metal nitride surface layer made of a nitride of the second metal and arranged between the upper metal layer and the first protective layer; and the lower metal nitride surface layer is in contact with the oxide semiconductor layer, and the upper metal nitride surface layer is in contact with the first protective layer.

In one embodiment, the semiconductor device further includes an etch stop layer covering a channel region of the oxide semiconductor layer.

In one embodiment, the oxide semiconductor layer is a layer containing an In—Ga—Zn—O based oxide.

In one embodiment, the oxide semiconductor layer is a layer containing a crystalline In—Ga—Zn—O based oxide.

### Advantageous Effects of Invention

In a semiconductor device according to one embodiment of the present invention, the source and drain electrodes include a metal nitride layer provided between a main layer (Al or Cu layer) and an upper metal layer and between the main layer and a lower metal layer (Ti or Mo layer). Thus, it is possible to suppress the mutual metal diffusion between the main layer and the upper metal layer and between the main layer and the lower metal layer, and it is therefore possible to suppress the increase in the resistance of the source and drain electrodes.

Where another metal nitride layer is arranged between the upper metal layer or the lower metal layer and the oxide semiconductor layer, it is possible to suppress the oxidation-reduction reaction between the oxide semiconductor and Ti or Mo, and it is possible to suppress the variation of the TFT threshold value.

Moreover, where another metal nitride layer is arranged between the upper metal layer and a protective layer made of an insulating oxide such as a silicon oxide (SiO₂) layer, it is possible to suppress the deterioration of the adhesion between the source and drain electrodes and the protective layer, thereby increasing the production yield.

### BRIEF DESCRIPTION OF DRAWINGS

FIG. 1 A schematic cross-sectional view of an oxide semiconductor TFT 101 according to a first embodiment.

FIG. 2 (a) is a schematic plan view of a semiconductor device (active-matrix substrate) 201 according to the first embodiment of the present invention, (b) and (c) are cross-sectional views taken along line A-A′ and line D-D′, respectively, from the plan view shown in (a).

FIG. 3 (a1) to (f1) and (a2) to (f2) are cross-sectional views illustrating steps of an example method for manufacturing the semiconductor device 201.

FIG. 4 (g1) to (i1) and (g2) to (i2) are cross-sectional views illustrating steps of the example method for manufacturing the semiconductor device 201.

FIG. 5 (j1) to (l1) and (j2) to (l2) are cross-sectional views illustrating steps of the example method for manufacturing the semiconductor device 201.

FIG. 6 A schematic cross-sectional view of an oxide semiconductor TFT 102 according to a second embodiment.

FIG. 7 A schematic cross-sectional view of an oxide semiconductor TFT 103 according to a third embodiment.

FIG. 8 (a) is a schematic plan view of a semiconductor device (active-matrix substrate) 204 according to a fourth embodiment of the present invention, and (b) and (c) are cross-sectional view taken along line A-A′ and line D-D′, respectively, from the plan view shown in (a).

FIG. 9 (a) is a schematic plan view of a semiconductor device (active-matrix substrate) 205 according to the fourth embodiment of the present invention, and (b) and (c) are cross-sectional view taken along line A-A′ and line D-D′, respectively, from the plan view shown in (a).

FIG. 10 (a1) to (d1) and (a2) to (d2) are cross-sectional views illustrating steps of an example method for manufacturing the semiconductor device 205.

FIG. 11 (e1) to (g1) and (e2) to (g2) are cross-sectional views illustrating steps of the example method for manufacturing the semiconductor device 205.

FIG. 12 (h1) to (j1) and (h2) to (j2) are cross-sectional views illustrating steps of the example method for manufacturing the semiconductor device 205.

### DESCRIPTION OF EMBODIMENTS

As described above, some conventional oxide semiconductor TFTs use source and drain electrodes having a structure (Ti/Al/Ti or Ti/Cu/Ti) in which the main layer (Cu or Al layer) is sandwiched between Ti layers for purposes such as suppressing the contact resistance between the source and drain electrodes and the oxide semiconductor layer.

However, the present inventor conducted a study to discover that with such a conventional oxide semiconductor TFT described above, if a heat treatment process is performed for some purpose after the formation of the source and drain electrodes, metals mutually diffuse between the main layer and the Ti layer. Such a heat treatment process may be a heat treatment (e.g., 250° C. or more and 450° C. or less) for reducing the oxygen deficiency in the oxide semiconductor layer, for example. As a result, the purity of the main layer may decrease, thereby increasing the resistance.

This problem was discovered by the present inventor, and had not been recognized in the art. It was also found that a similar problem occurs also when an Mo layer is used instead of a Ti layer.

The present inventor further conducted an in-depth study in order to solve the problem set forth above to discover that the mutual metal diffusion between a main layer and a metal layer of Ti or Mo can be suppressed by arranging a layer of a nitride of that metal (i.e., a titanium nitride (TiN) layer or a molybdenum nitride (MoN) layer) between the metal layer and the main layer, thus arriving at the present invention.

### First Embodiment

A semiconductor device according to a first embodiment of the present invention will now be described with reference to the drawings. A semiconductor device of the present embodiment includes an oxide semiconductor TFT. Note that a semiconductor device of the present embodiment only needs to include an oxide semiconductor TFT, and may be anything from a wide variety of applications, including active-matrix substrates, various display devices, electronic devices, etc.

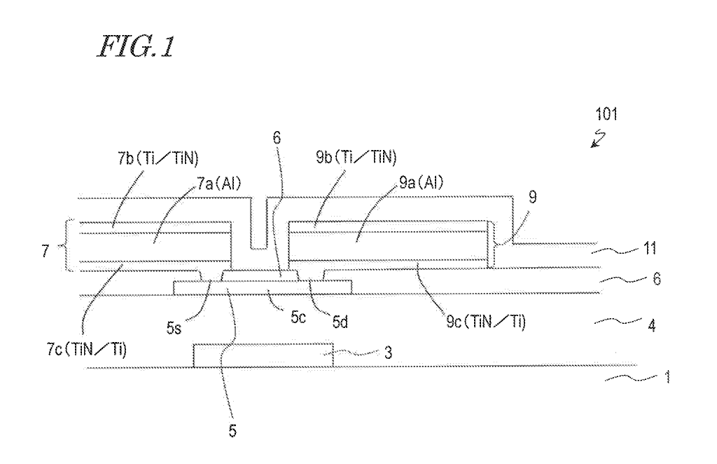

FIG. 1 is a schematic cross-sectional view of an oxide semiconductor TFT 101 of the present embodiment.

The oxide semiconductor TFT 101 includes a gate electrode 3 supported on a substrate 1, a gate insulating layer 4 covering the gate electrode 3, an oxide semiconductor layer 5 arranged so as to overlap with the gate electrode 3 with the gate insulating layer 4 therebetween, a source electrode 7, and a drain electrode 9. The oxide semiconductor layer 5 includes a channel region 5c, and a source contact region 5s and a drain contact region 5d located on the opposite sides of the channel region. The source electrode 7 is formed so as to be in contact with the source contact region 5s, and the drain electrode 9 is formed so as to be in contact with the drain contact region 5d. In the present embodiment, the source electrode 7 and the drain electrode 9 are formed of the same multilayer film.

The source electrode 7 of the present embodiment has a multilayer structure including a main layer 7a containing Al or Cu (hereinafter referred to as a “first metal”), an upper layer 7b provided on the upper surface of the main layer 7a, and a lower layer 7c provided on the lower surface of the main layer 7a. Each of the upper layer 7b and the lower layer 7c is a multilayer film including a metal nitride layer made of a nitride of Ti or Mo (hereinafter referred to as a “second metal”) and a metal layer made of a second metal, arranged in this order from the main layer 7a. In the example illustrated herein, Al is used as the first metal, and Ti as the second metal. Therefore, the main layer 7a is an Al layer. The upper layer 7b and the lower layer 7c each include a TiN layer and a Ti layer arranged in this order from the side of the main layer 7a. In the present specification, the structure of a multilayer film is sometimes represented by sequentially specifying the films thereof starting from the top film. According to this, the upper layer 7b is represented as Ti/TiN, and the lower layer 7c as TiN/Ti.

The source electrode 7 is electrically connected to a source line. The source line may be formed of the same multilayer conductive film as the source electrode 7. In the example illustrated herein, the source electrode 7 is a part of the source line and is formed integral with the source line.

Similar to the source electrode 7, the drain electrode 9 has a multilayer structure including an Al layer or Cu layer (main layer) 9a, an upper layer 9b provided on the upper surface of the main layer 9a, and a lower layer 9c provided on the lower surface of the main layer 9a. Each of the upper layer 9b and the lower layer 9c is a multilayer film including a metal nitride layer made of a nitride of Ti or Mo (second metal), and a metal layer made of the second metal, arranged in this order from the side of the main layer 9a. In the example illustrated herein, the main layer 9a is an Al layer. The upper layer 9b has a multilayer structure represented as Ti/TiN, and the lower layer 9c as TiN/Ti. Where the oxide semiconductor TFT 101 is used as a switching element of an active-matrix substrate, the drain electrode 9 is electrically connected to a pixel electrode (not shown).

Note that in the present specification, the metal layer and the metal nitride layer included in the upper layers 7b, 9b are sometimes called the upper metal layer and the upper metal nitride layer, respectively. Similarly, the metal layer and the metal nitride layer included in the lower layers 7c, 9c are sometimes called the lower metal layer and the lower metal nitride layer, respectively.

An etch stop layer 6 may be further provided covering the channel region 5c of the oxide semiconductor layer 5. In the illustrated example, the etch stop layer 6 is formed so as to cover the oxide semiconductor layer 5 and the gate insulating layer 4. The etch stop layer 6 has openings therein that expose the source and drain contact regions 5s and 5d. Note that the etch stop layer 6 may be formed so as to cover generally the entire substrate. For example, the etch stop layer 6 may be extended to the terminal portion (not shown) on the substrate.

The oxide semiconductor TFT 101 may be covered by a first protective layer 11. In the illustrated example, the first protective layer 11 is provided so as to be in contact with the upper surface of the source and drain electrodes 7, 9.

In the oxide semiconductor TFT 101 of the present embodiment, the source and drain electrodes 7, 9 include a metal nitride layer (a TiN layer or an MoN layer) interposed between the main layers 7a, 9a and a metal layer (a Ti layer or an Mo layer) made of the second metal. Since the main layers 7a, 9a and the metal layer are not in contact with each other, it is possible to suppress the mutual metal diffusion between the metal layer and the main layers 7a, 9a. As a result, it is possible to suppress the increase in the resistance of the main layers 7a, 9a of the source and drain electrodes 7, 9. Where the source line is formed from the same multilayer conductive film as the source electrode 7, it is possible to suppress the increase in the resistance of the source line for the same reason. Therefore, it is possible to suppress characteristic deterioration (an increase in the on-resistance) deriving from an increase in the resistance of the source and drain electrodes 7, 9 or the source line.

Note that a comparative example may use a structure (e.g., TiN/Al/TiN) in which only a metal nitride layer (a TiN or MoN layer) is arranged on the upper surface and the lower surface of the main layer in the source and drain electrodes. Also in this case, it is possible to reduce the problem deriving from the metal diffusion as described above. However, in order to suppress the reaction between the main layer and the oxide semiconductor layer, the thickness of the TiN layer needs to be as large as over 50 nm, for example. Since a metal nitride such as TiN has a large film stress, peeling is likely to occur if it deposits on a chamber sidewall of a deposition apparatus (e.g., a PVD apparatus). Therefore, if the thickness of the TiN film increases, dust such as particles generated by peeling may possibly attach on the substrate in the deposition apparatus, thereby causing a pattern failure and lowering the production yield. In contrast, in the present embodiment, the TiN layer only needs to have a thickness such that it is possible to prevent the metal diffusion between the Ti layer and the Al layer, and the TiN layer can be made thinner than in the comparative example. Therefore, it is possible to suppress the problem deriving from the peeling of the film deposited on the chamber sidewall.

The oxide semiconductor layer 5 of the oxide semiconductor TFT 101 contains IGZO, for example. Now, IGZO refers to an oxide of In (indium), Ga (gallium) and Zn (zinc), and generally includes In—Ga—Zn—O based oxides. IGZO may be amorphous or crystalline. A preferred crystalline IGZO layer is a crystalline IGZO layer where the c axis is oriented generally perpendicular to the layer surface. A crystalline structure of such an IGZO layer is disclosed in Japanese Laid-Open Patent Publication No. 2012-134475, for example. The entire disclosure of Japanese Laid-Open Patent Publication No. 2012-134475 is herein incorporated by reference. The oxide semiconductor layer 5 may be a layer of InGaO₃ (ZnO)₅, magnesium oxide zinc (MgₓZn₁₋ₓO), cadmium oxide zinc (CdₓZn₁₋ₓO), or cadmium oxide (CdO). Alternatively, it may be a ZnO layer with one or more impurity elements added thereto, such as group 1 elements, group 13 elements, group 14 elements, group 15 elements or group 17 elements. Such a ZnO layer may be in an amorphous state, a polycrystalline state, or a microcrystalline state where the amorphous state and the polycrystalline state coexist.

The source and drain electrodes 7, 9 may be a multilayer film including another conductive layer, in addition to the layers described above. Advantageous effects described above can be obtained also in such a case, if a metal nitride layer is interposed between the metal layer and the main layers 7a, 9a. If the main layers 7a, 9a are in contact with the metal nitride layer, the mutual diffusion between the metal layer and the main layers 7a, 9a can be suppressed more effectively.

The first protective layer 11 may be an inorganic insulating layer such as an SiO₂ layer, for example. The first protective layer 11 may function as a passivation layer.

While the oxide semiconductor TFT 101 shown in FIG. 1 has a bottom-gate structure, it may have a top-gate structure. The oxide semiconductor TFT 101 may include no etch stop layer 6 (a channel-etched TFT).

Next, the structure of a semiconductor device having the oxide semiconductor TFT 101 will be described with reference to an example active-matrix substrate for a display device.

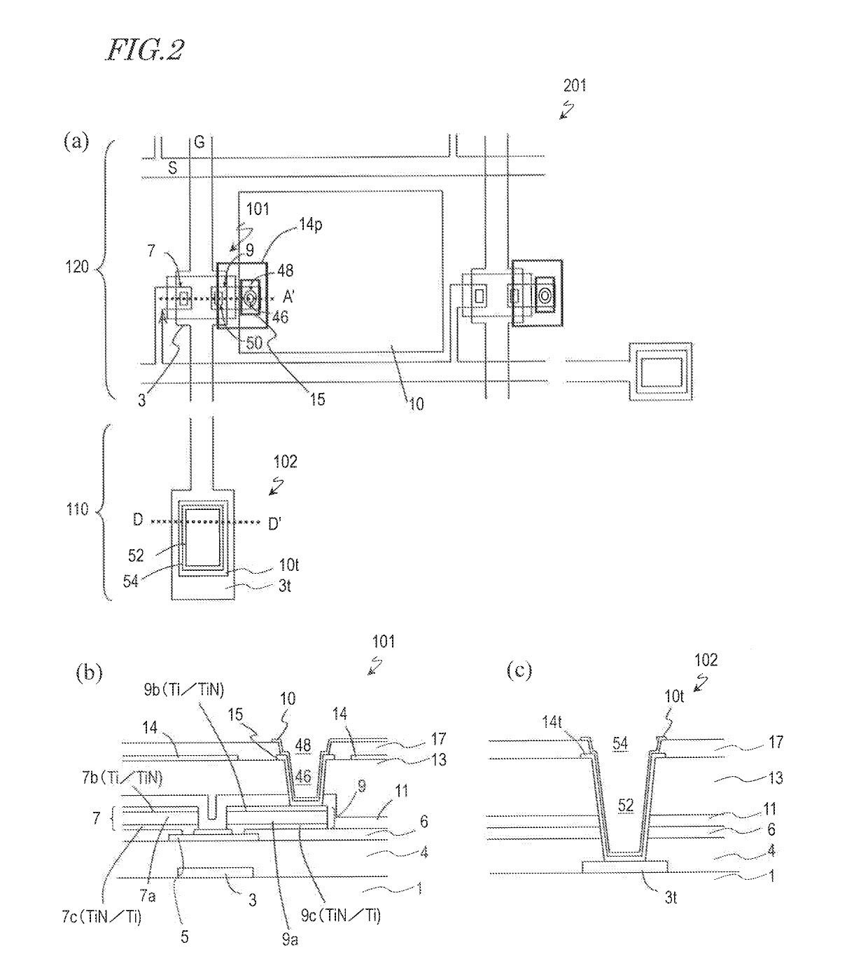

FIG. 2(a) is a schematic plan view of a semiconductor device (active-matrix substrate) 201. FIGS. 2(b) and 2(c) are schematic cross-sectional views of the semiconductor device 201, taken along line A-A′ and line D-D′, respectively, from the plan view shown in FIG. 2(a).

First, reference is made to FIG. 2(a). The semiconductor device 201 includes a display area (active area) 120 contributing to display production, and a peripheral area (bezel area) 110 located outside the display area 120.

A plurality of gate lines G and a plurality of source lines S are formed in the display area 120, and each region surrounded by these lines is a “pixel”. A plurality of pixels are arranged in a matrix pattern. A pixel electrode 10 is formed in each pixel. Pixel electrodes 10 of different pixels are separated from one another. In each pixel, the oxide semiconductor TFT 101 is formed in the vicinity of each intersection between the source lines S and the gate lines G. In the example illustrated herein, the configuration of the oxide semiconductor TFT 101 is similar to that described above with reference to FIG. 1. The source electrode 7 and the drain electrode 9 of each the oxide semiconductor TFT 101 are in contact with the oxide semiconductor layer 5 in an opening (contact hole) 50 formed in the etch stop layer 6.

The gate electrode 3 of the oxide semiconductor TFT 101 is formed integral with the gate line G using the same conductive film as the gate line G. In the present specification, layers that are formed by using the same conductive film as the gate lines G will be referred to collectively as a “gate line layer”. Therefore, the gate line layer includes the gate line G and the gate electrode (a portion that functions as the gate of the oxide semiconductor TFT 101) 3. In the present specification, a pattern including the gate electrode 3 and the gate line G formed integral with each other may also be referred to as the “gate line G”. As the gate line G is seen from the substrate normal direction, the gate line G may include a portion extending in a predetermined direction and an extended portion extending off this portion in a direction different from the predetermined direction, with the extended portion functioning as the gate electrode 3. Alternatively, when viewed along a normal to the substrate, the gate line G may include a plurality of straight portions having a constant width and extending in a predetermined direction, with a part of each straight portions overlapping with the channel region of the TFT 101 and functioning as the gate electrode 3.

The source electrode 7 and the drain electrode 9 of the oxide semiconductor TFT 101 are formed of the same conductive film as the source line S. In the present specification, layers that are formed by using the same conductive film as the source line S will be referred to collectively as a “source line layer”. Therefore, the source line layer includes the source line S, the source electrode 7 and the drain electrode 9. The source electrode 7 may be formed integral with the source line S. The source line S may include a portion extending in a predetermined direction and an extended portion extending off this portion in a direction different from the predetermined direction, with the extended portion functioning as the source electrode 7.

In the present embodiment, a common electrode 14 is provided between the pixel electrode 10 and the oxide semiconductor TFT 101 so as to oppose the pixel electrode 10. A common signal (COM signal) is applied to the common electrode 14. The common electrode 14 of the present embodiment includes an opening 14p for each pixel. A contact portion between the pixel electrode 10 and the drain electrode 9 of the oxide semiconductor TFT 101 is formed in the opening 14p. In the contact portion, the pixel electrode 10 and the drain electrode 9 may be connected together by a connection layer 15 formed of the same conductive film (transparent conductive film) as the common electrode 14. Note that the common electrode 14 may be formed generally over the entire display area 120 (except for the openings 14p described above).

A terminal portion 102 for electrically connecting the gate line G or the source line S with an external line is formed in the peripheral area 110.

Next, referring to FIG. 2(b), a cross-sectional structure of a TFT formation region including the oxide semiconductor TFT 101 will be described.

In the TFT formation region, the semiconductor device 201 includes a first protective layer (e.g., an SiO₂ layer) 11 covering the oxide semiconductor TFT 101, a second protective layer (e.g., a transparent insulating resin layer) formed on the first protective layer 11, the common electrode 14 formed on the second protective layer 13, a third protective layer (e.g., an SiO₂ layer or an SiN layer) 17 formed on the common electrode 14, and the pixel electrode 10. The pixel electrode 10 is arranged so as to oppose the common electrode 14 with the third protective layer 17 therebetween. The pixel electrode 10 and the common electrode 14 are formed of a transparent conductive film such as IZO or ITO, for example. The common electrode 14 includes the opening 14p therein. In the opening 14p, a contact hole 46 is formed through the first protective layer 11 and the second protective layer 13, reaching at least a portion of the drain electrode 9. The connection layer 15 formed of the same conductive film as the common electrode 14 and electrically separated from the common electrode 14 may be formed in the opening 14p. The connection layer 15 is in contact with the drain electrode 9 in the contact hole 46. As can be seen from FIG. 2(a), the opening 14p and the connection layer 15 are arranged so as to overlap with at least a portion of the drain electrode 9 when viewed along a normal to the substrate.

A contact hole 48 is formed in the third protective layer 17. The contact hole 48 is arranged in the opening 14p of the common electrode 14 when viewed along a normal to the substrate. Therefore, the side surface of the common electrode 14 on the side of the opening 14p is covered by the third protective layer 17, and is not exposed on the sidewall of the contact hole 48. At least a portion of the contact hole 48 is arranged so as to overlap with the contact hole 46. Here, the contact hole 46 is arranged inside the contact hole 48 when viewed along a normal to the substrate (see FIG. 2(a)). Thus, it is possible to reduce the area needed for contact. A portion of the pixel electrode 10 is also formed in the contact holes 46 and 48, and is electrically connected to the drain electrode 9 via the connection layer 15 therebetween.

Note that the structure for connecting together the drain electrode 9 and the pixel electrode 10 is not limited to the illustrated structure. For example, the pixel electrode 10 and the drain electrode 9 may be brought into direct contact with each other without providing the connection layer 15. Note however that with the provision of the connection layer 15, even if the pixel electrode 10 has a step separation, or the like, in the contact holes 46 and 48, the connection between the pixel electrode 10 and the drain electrode 9 is more reliably ensured by the connection layer 15. Thus, it is possible to form a highly-reliable contact portion having a redundant structure.

At least a portion of the pixel electrode 10 may overlap with the common electrode 14 via the third protective layer 17 therebetween when viewed along a normal to the substrate 1. Thus, a capacitor including the third protective layer 17 as the dielectric layer is formed in a portion where the pixel electrode 10 and the common electrode 14 overlap with each other. This capacitor can function as a storage capacitor (transparent storage capacitor) in a display device. A storage capacitor having a desirable capacitance is obtained by appropriately adjusting the material and the thickness of the third protective layer 17, and the area of the portion forming the capacitor. Therefore, it is not necessary to separately form a storage capacitor in the pixel by utilizing the same metal film as the source line, for example. Therefore, it is possible to suppress the decrease in the aperture ratio due to the formation of a storage capacitor using a metal film.

Next, referring to FIG. 2(c), an example configuration of the terminal portion 102 will be described.

The terminal portion 102 includes: a lower conductive layer 3t formed on the substrate 1; the gate insulating layer 4, the etch stop layer 6, the first protective layer 11, the second protective layer 13 and the third protective layer 17 extending so as to cover the lower conductive layer 3t; an upper conductive layer 14t formed of the same conductive film as the common electrode 14; and an external connection layer 10t formed of the same conductive film as the pixel electrode 10. The upper conductive layer 14t is in contact with the lower conductive layer 3t in an opening 52 formed through the gate insulating layer 4, the etch stop layer 6, the first protective layer 11 and the second protective layer 13. The external connection layer 10t is in contact with the upper conductive layer 14t in the opening 52 and in an opening 54 provided in the third protective layer 17. Therefore, at the terminal portion 102, the electrical connection between the external connection layer 10t and the lower conductive layer 3t is ensured via the upper conductive layer 14t. According to the present embodiment, it is possible to form a highly-reliable terminal portion 102 having a redundant structure by providing the upper conductive layer 14t interposed between the external connection layer 10t and the lower conductive layer 3t.

The lower conductive layer 3t is formed of the same conductive film as the gate electrode 3, for example. The lower conductive layer 3t may be connected to the gate line G (gate terminal portion). Alternatively, it may be connected to the source line S (source terminal portion).

The configuration of the semiconductor device 201 of the present embodiment is not limited to the configuration shown in FIG. 2. It can be changed as necessary according to the display mode of the display device to which the semiconductor device 201 is applied.

The semiconductor device 201 of the present embodiment may be applicable to a display device of an FFS mode, for example. In such a case, each pixel electrode 10 preferably includes a plurality of slit-shaped openings. On the other hand, if the common electrode 14 is arranged at least under the slit-shaped openings of the pixel electrode 10, the common electrode 14 can function as the counter electrode for the pixel electrode, thereby applying a transverse electric field through liquid crystal molecules. In the present embodiment, the common electrode 14 accounts for generally the entire pixel (excluding the opening 14p). Thus, the portion where the pixel electrode 10 and the common electrode 14 overlap with each other can have a large area, and it is therefore possible to increase the area of the storage capacitor.

Note that the semiconductor device 201 of the present embodiment may be applicable to display devices of operation modes other than the FFS mode. For example, it may be applied to a vertical electric field-driven display device operating in a VA mode, or the like. In such a case, the common electrode 14 and the third protective layer 17 may be absent. Alternatively, a transparent conductive layer opposing the pixel electrode 10 and functioning as a storage capacitor electrode may be provided, instead of the common electrode 14, thereby forming a transparent storage capacitor in the pixel.

<Method for Manufacturing Semiconductor Device 201>

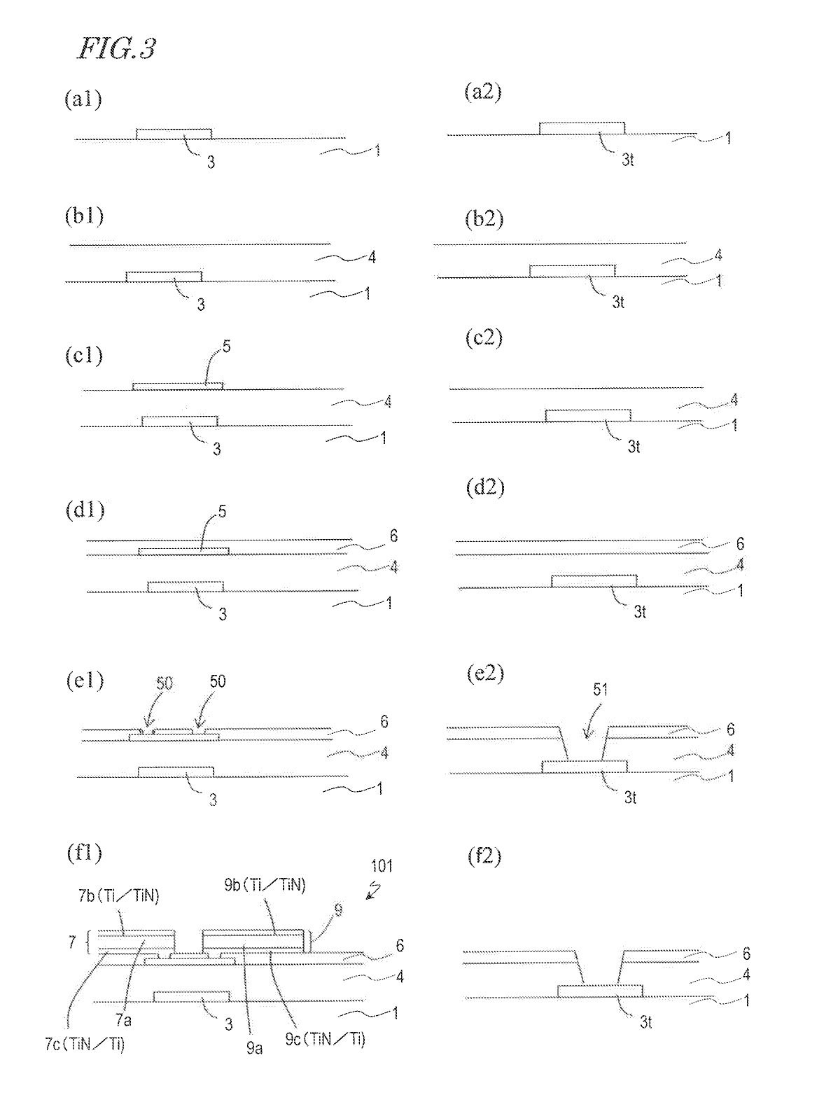

FIGS. 3 to 5 are cross-sectional views illustrating steps of an example method for manufacturing the semiconductor device 201, wherein (a1) to (l1) show the cross-sectional structure of the TFT formation region whereas (a2) to (l2) show that of the terminal portion formation region.

First, a gate line metal film (thickness: 50 nm or more and 500 nm or less, for example) (not shown) is formed on the substrate 1 by a sputtering method, or the like.

Then, the gate line metal film is patterned, thereby forming a gate line layer. Thus, the gate electrode 3 of the TFT is formed integral with the gate line in the TFT formation region whereas the lower conductive layer 3t of the terminal portion 102 is formed in the terminal portion formation region, as shown in FIGS. 3(a1) and 3(a2). The patterning is done by forming a resist mask (not shown) by a known photolithography method, and then removing portions of the gate line metal film that are not covered by the resist mask. The resist mask is removed after the patterning.

For example, the substrate 1 may be a glass substrate, a silicon substrate, a heat-resistant plastic substrate (resin substrate), or the like.

The gate line metal film is herein a multilayer film of molybdenum niobium (MoNb)/aluminum (Al). Note that there is no particular limitation on the material of the gate line metal film. It may be a film containing a metal such as aluminum (Al), tungsten (W), molybdenum (Mo), tantalum (Ta), chromium (Cr), titanium (Ti), copper (Cu), etc., an alloy thereof, or a metal nitride thereof.

Next, as shown in FIGS. 3(b1) and 3(b2), the gate insulating layer 4 is formed so as to cover the gate line layer (the gate electrode 3, the lower conductive layer 3t and the gate line). The gate insulating layer 4 can be formed by a CVD method, or the like.

The gate insulating layer 4 may be a silicon oxide (SiOx) layer, a silicon nitride (SiNx) layer, a silicon oxide nitride (SiOxNy; x>y) layer, a silicon nitride oxide (SiNxOy; x>y) layer, or the like. The gate insulating layer 4 may have a multilayer structure. For example, it may include a silicon nitride layer, a silicon nitride oxide layer, or the like, formed on the substrate side (lower layer) so as to prevent diffusion of impurities, etc., from the substrate 1, and a silicon oxide layer, a silicon oxide nitride layer, or the like, formed thereon (upper layer) so as to ensure insulation. Note that where an oxygen-containing layer (e.g., an oxide layer such as SiO₂) is used as the uppermost layer of the gate insulating layer 4 (i.e., a layer to be in contact with the oxide semiconductor layer), if oxygen deficiency occurs in the oxide semiconductor layer, oxygen contained in the oxide layer can allow for recovery from oxygen deficiency, and it is therefore possible to effectively reduce oxygen deficiency in the oxide semiconductor layer.

Next, as shown in FIGS. 3(c1) and 3(c2), the oxide semiconductor layer 5 is formed on the gate insulating layer in the TFT formation region. Specifically, an oxide semiconductor film having a thickness of 30 nm or more and 200 nm or less, for example, is formed on the gate insulating layer 4 by using a sputtering method. Then, the oxide semiconductor film is patterned by photolithography, thereby obtaining the oxide semiconductor layer 5. At least a portion of the oxide semiconductor layer 5 is arranged so as to overlap with the gate electrode 3 with the gate insulating layer 4 therebetween when viewed along a normal to the substrate 1.

Here, an In—Ga—Zn—O based amorphous oxide semiconductor film (thickness: 50 nm, for example) containing In, Ga and Zn at a ratio of 1:1:1 is patterned, thereby forming the oxide semiconductor layer 5.

Next, as shown in FIGS. 3(d1) and 3(d2), an etch stop (thickness: 30 nm or more and 200 nm or less, for example) 6 is formed on the oxide semiconductor layer 5 and the gate insulating layer 4. The etch stop layer 6 may be a silicon oxide film, a silicon nitride film, a silicon oxide nitride film, or a multilayer film thereof. Here, a silicon oxide film (SiO₂ film) having a thickness of 100 nm, for example, is formed by a CVD method as the etch stop layer 6.

By forming the etch stop layer 6, it is possible to reduce the process damage on the oxide semiconductor layer 5. Where an oxide film such as an SiOx film (including an SiO₂ film) is used as the etch stop layer 6, if oxygen deficiency occurs in the oxide semiconductor layer 5, oxygen contained in the oxide film can allow for recovery from oxygen deficiency, and it is therefore possible to effectively reduce oxygen deficiency in the oxide semiconductor layer 5.

Then, the etch stop layer 6 and the gate insulating layer 4 are etched by using a resist mask (not shown). In this process, etching conditions are selected depending on the material of each layer so that the etch stop layer 6 and the gate insulating layer 4 are etched and the oxide semiconductor layer 5 is not etched. Etching conditions as used herein include, where dry etching is used, the type of the etching gas, the temperature of the substrate 1, the degree of vacuum in the chamber, etc. Where wet etching is used, they include the type of the etchant, the etching time, etc.

Thus, as shown in FIG. 3(e1), in the TFT formation region, the openings 50 are formed in the etch stop layer 6 so as to expose opposite sides of a region of the oxide semiconductor layer 5 to be the channel region. In this etching, the oxide semiconductor layer 5 functions as an etch stop. Note that the etch stop layer 6 can be patterned so as to at least cover the region to be the channel region. Then, it is possible to reduce the etching damage on the channel region of the oxide semiconductor layer 5 during the source-drain separation step, for example, thereby suppressing deterioration of the TFT characteristics.

On the other hand, as shown in FIG. 3(e2), in the terminal portion formation region, as a result of etching the etch stop layer 6 and the gate insulating layer 4 at the same time (GI/ES simultaneous etching), an opening 51 that exposes the lower conductive layer 3t is formed through the etch stop layer 6 and the gate insulating layer 4.

Next, although not shown, a source line metal film (thickness: 50 nm or more and 500 nm or less, for example) is formed on the etch stop layer 6 and in the openings 50 and 51. The source line metal film is formed by, for example, a sputtering method, or the like. Here, a multilayer film is formed as the source line metal film, including a Ti film, a TiN film, an Al film, a TiN film and a Ti film stacked in this order from the side of the oxide semiconductor layer 5. The thickness of the Al film to be the main layer is 100 nm or more and 400 nm or less, for example. In each of the upper layer and the lower layer of the main layer, the thickness of the TiN film is preferably set to be smaller than the thickness of the Ti film. More preferably, it is set to be less than ½ the thickness of the Ti film. Thus, by suppressing the thickness of the TiN film, it is possible to relax the film stress of the deposition film to deposit on the chamber sidewall of a deposition apparatus (e.g., a PVD apparatus), and to suppress the generation of particles, which derives from peeling. The TiN films formed in the upper layer and the lower layer each have a thickness of 5 nm or more and 50 nm or less, for example. If the thickness of the TiN film is 5 nm or more and, it is possible to more effectively suppress metal diffusion between the Ti film and the Al film. If the thickness of the TiN film is 50 nm or less, it is possible to suppress the peeling problem as described above. The Ti film formed in the upper layer and the lower layer of the main layer each have a thickness of 50 nm or more and 200 nm or less, for example.

Note that a Cu film may be used instead of an Al film as the main layer, and an Mo film and an MoN film may be used instead of a Ti film and a TiN film as the metal film and the metal nitride film in the upper layer and the lower layer. Also in such a case, the thickness range may be similar to those described above for the metal film and the metal nitride film in the main layer, the upper layer and the lower layer.

Next, the source line metal film is patterned so as to form the source electrode 7 and the drain electrode 9 in the TFT formation region as shown in FIGS. 3(f1) and 3(f2). The source line metal film is removed in the terminal portion formation region.

The source electrode 7 and the drain electrode 9 are each connected to the oxide semiconductor layer 5 in the opening 50. Portions of the oxide semiconductor layer 5 that are in contact with the source electrode 7 and the drain electrode 9 are the source contact region and the drain contact region, respectively. Thus, the oxide semiconductor TFT 101 is obtained.

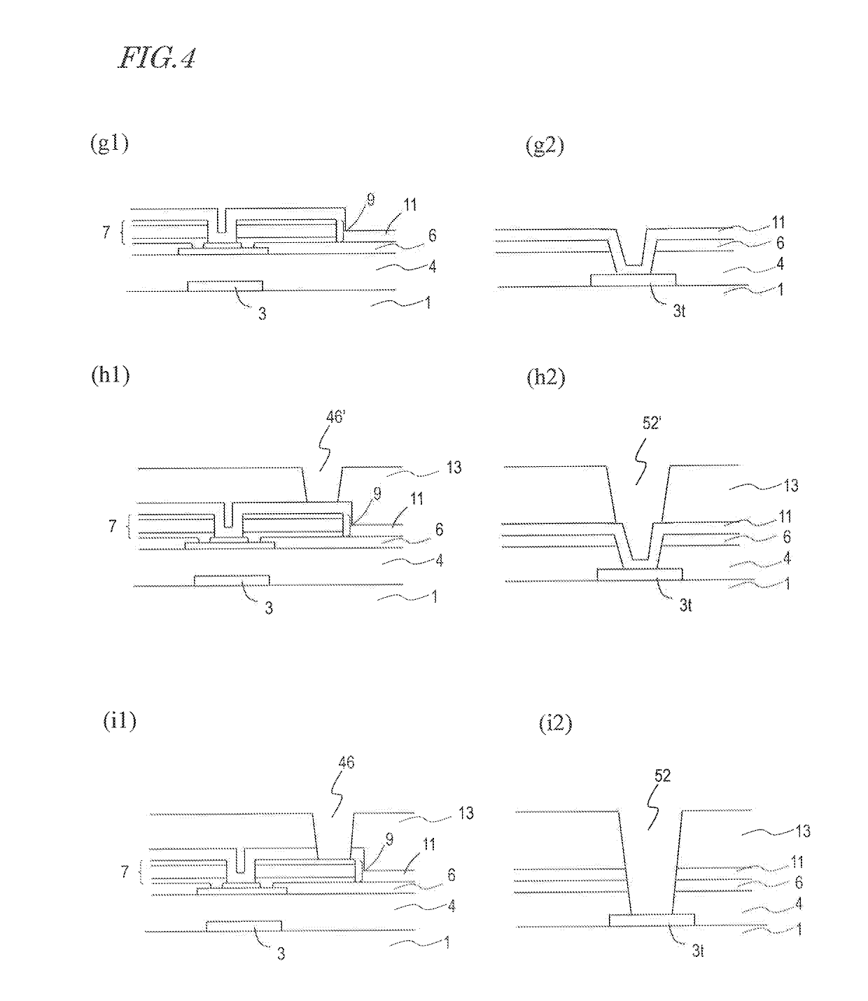

Next, as shown in FIGS. 4(g1) and 4(g2), the first protective layer 11 is formed so as to cover the oxide semiconductor TFT 101. The first protective layer 11 may be an inorganic insulating film (passivation film) such as a silicon oxide (SiOx) film, a silicon nitride (SiNx) film, a silicon oxide nitride (SiOxNy; x>y) film, a silicon nitride oxide (SiNxOy; x>y) film, or the like. Here, an SiO₂ layer having a thickness of 200 nm, for example, is formed by a CVD method, for example, as the first protective layer 11.

Then, although not shown, the entire substrate is subjected to a heat treatment (annealing process). The reason for this will now be described.

Depending on the TFT manufacturing process, oxygen deficiency may possibly occur in the oxide semiconductor layer 5 (especially, in the channel region). Thus, the conductivity of the channel region is high, and if the TFT is completed as it is, the off-leakage current may be large and desirable characteristics may not be realized. In contrast, if a heat treatment is performed, the channel region of the oxide semiconductor layer 5 is oxidized, thereby reducing the oxygen deficiency in the channel region and realizing desirable TFT characteristics.

While there is no particular limitation on the temperature of the heat treatment, it is 250° C. or more and 450° C. or less, for example. Depending on the material of the second protective layer 13, the heat treatment may be performed after the formation of the second protective layer 13.

Note that with a conventional semiconductor device including source and drain electrodes having a three-layer structure of Ti/Al (or Cu)/Ti, for example, this heat treatment causes diffusion at the interface between the Ti layer and the Al layer where Ti diffuses into the Al layer and Al diffuses into the Ti layer, thereby lowering the purity of the Al layer. In contrast, in the present embodiment, since a TiN layer is provided between the Al layer (or Cu layer) and the Ti layer and it is possible to suppress the mutual diffusion between Ti and Al, thus suppressing the program described above.

Next, as shown in FIGS. 4(h1) and 4(h2), the second protective layer 13 is formed on the first protective layer 11. The second protective layer 13 is obtained by forming and patterning an organic insulating film, for example. Here, a positive-type photosensitive resin film having a thickness of 2000 nm, for example, is used as the second protective layer 13.

As shown in FIG. 4(h1), in the TFT formation region, the second protective layer 13 has an opening 46′ provided through a portion of the second protective layer 13 that is located above the drain electrode 9 so as to expose the first protective layer 11. As shown in FIG. 4(h2), in the terminal portion formation region, an opening 52′ is provided through a portion of the second protective layer 13 that is located above the opening 51 so as to expose the first protective layer 11.

Note that the materials of these protective layers 11 and 13 are not limited to those described above. The materials of the protective layers 11 and 13 and the etching conditions can be selected so that the second protective layer 13 can be etched without etching the first protective layer 11. Therefore, the second protective layer 13 may be an inorganic insulating layer, for example.

Next, the first protective layer 11 is etched away by using the second protective layer 13 as an etching mask. Thus, as shown in FIG. 4(i1), in the TFT formation region, an opening 46 is obtained, exposing the surface of the drain electrode 9. As shown in FIG. 4(i2), in the terminal portion formation region, the opening 52 is obtained, exposing the surface of the lower conductive layer 3t.

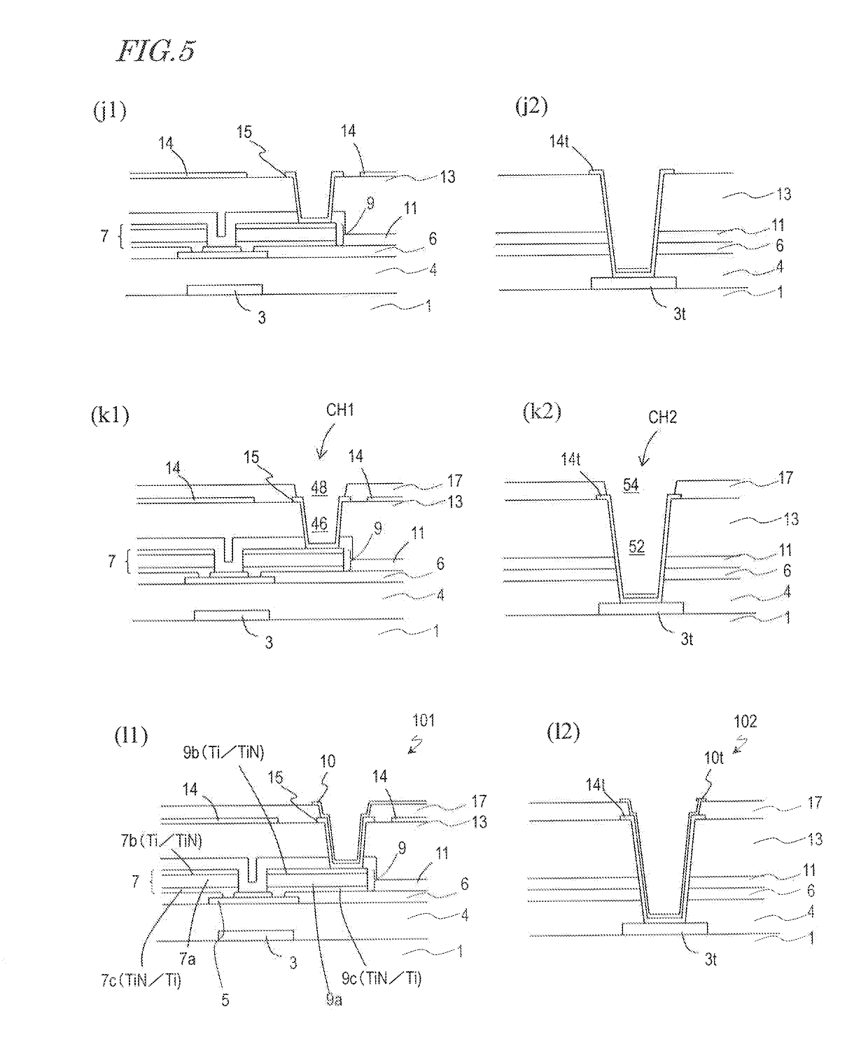

Then, a transparent conductive film (not shown) is formed on the second protective layer 13 and in the openings 46 and 52 by a sputtering method, for example, and the transparent conductive film is patterned. A known photolithography can be used for the patterning. Thus, as shown in FIG. 5(j1), in the TFT formation region, the common electrode 14 and the connection layer 15, which is in contact with the drain electrode 9 in the opening 46, are obtained. The common electrode 14 may be formed so as to cover generally the entire display area. The connection layer 15 is arranged inside the opening 46 and on the peripheral portion of the opening 46, and is separated from the common electrode 14. As shown in FIG. 5(j2), in the terminal portion formation region, the upper conductive layer 14t is obtained, which is in contact with the lower conductive layer 3t in the opening 52.

The transparent conductive film may be an ITO (indium tin oxide) film (thickness: 50 nm or more and 200 nm or less), an IZO film, a ZnO film (zinc oxide film), or the like, for example. Here, an ITO film having a thickness of 100 nm, for example, is used as the transparent conductive film.

Next, the third protective layer 17 is formed by a CVD method, for example, so as to cover the entire surface of the substrate 1. Next, a resist mask (not shown) is formed on the third protective layer 17, and the third protective layer 17 is etched. Thus, as shown in FIGS. 5(k1) and 5(k2), an opening 48 exposing the connection layer 15, and the opening 54 exposing the upper conductive layer 14t are formed through the third protective layer 17. In the example illustrated herein, the opening 48 is arranged so as to overlap with the opening 46 when viewed along a normal to the substrate 1, and the openings 46 and 48 together form a contact hole CH1. The opening 54 is arranged so as to overlap with the opening 52, and the openings 52 and 54 together form a contact hole CH2.

There is no particular limitation on the third protective layer 17, and it may be a silicon oxide (SiOx) film, a silicon nitride (SiNx) film, a silicon oxide nitride (SiOxNy; x>y) film, a silicon nitride oxide (SiNxOy; x>y) film, or the like, for example. In the present embodiment, since the third protective layer 17 is utilized also as a capacitor insulating film of the storage capacitor, it is preferred to appropriately select the material and the thickness of the third protective layer 17 so as to obtain a predetermined capacitance C_{CS}. An SiN film or an SiO₂ film having a thickness of 150 nm or more and 400 nm or less, for example, may be used as the third protective layer 17.

Then, a transparent conductive film (not shown) is formed on the third protective layer 17 and in the contact holes CH1 and CH2 by a sputtering method, for example, and the transparent conductive film is patterned. A known photolithography can be used for the patterning. Thus, as shown in FIGS. 5(l1) and 5(l2), the pixel electrode 10 and the external connection layer 10t are obtained from the transparent conductive film. The pixel electrode 10 is in contact with the connection layer 15 in the contact hole CH1, and is connected to the drain electrode 9 via the connection layer 15 therebetween. The external connection layer 10t is in contact with the upper conductive layer 14t in the contact hole CH2, and is connected to the lower conductive layer 3t via the upper conductive layer 14t therebetween. At least a portion of the pixel electrode 10 is arranged so as to overlap with the common electrode 14 with the third protective layer 17 therebetween, thereby forming a transparent storage capacitor. Thus, the semiconductor device 201 is manufactured.

The transparent conductive film for forming the pixel electrode 10 and the external connection layer 10t may be an ITO (indium tin oxide) film (thickness: 50 nm or more and 150 nm or less), an IZO film, a ZnO film (zinc oxide film), or the like, for example. Here, an ITO film having a thickness of 100 nm, for example, is used as the transparent conductive film.

### Second Embodiment

The oxide semiconductor TFT of the present embodiment is different from the oxide semiconductor TFT 101 (FIG. 1) described above in that one of the lower layer and the upper layer of the source and drain electrodes that is located closer to the oxide semiconductor layer further includes another metal nitride layer between the metal layer and the oxide semiconductor layer.

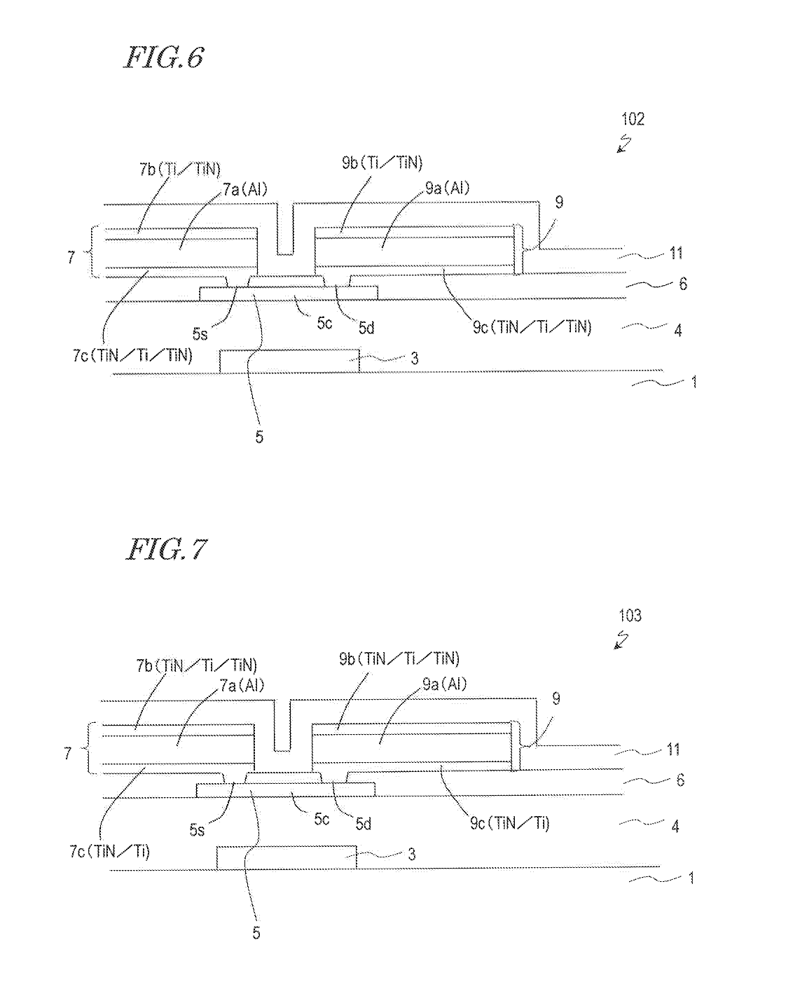

FIG. 6 is a cross-sectional view illustrating an oxide semiconductor TFT 102 according to the second embodiment of the present invention.

In the oxide semiconductor TFT 102 of the present embodiment, the lower layers 7c and 9c of the source electrode and the drain electrode further include a TiN layer on the side opposite to the main layers 7a and 9a of a Ti layer. Therefore, the lower layers 7c, 9c are a multilayer film including a TiN layer, a Ti layer and a TiN layer arranged in this order from the main layers 7a, 9a. That is, it has a three-layer structure of TiN/Ti/TiN. In the example illustrated herein, the TiN layer on the opposite side of the main layers 7a, 9a of a Ti layer is the lowermost layer, and is in contact with the oxide semiconductor layer 5. Otherwise, the configuration is generally the same as the oxide semiconductor TFT 101.

In the present embodiment, as in the first embodiment, it is possible to suppress the mutual metal diffusion between the Ti layer and the main layers 7a, 9a, and it is possible to suppress the increase in the resistance of the source and drain electrodes. It is also possible to obtain an advantageous effect of suppressing the variation of the TFT threshold value, as will be described below.

In a conventional oxide semiconductor TFT disclosed in Patent Document No. 1, etc., a Ti layer is provided between an Al or Cu layer of the source and drain electrodes and the oxide semiconductor layer. However, the present inventor conducted a study to discover that with a configuration where the Ti layer and the oxide semiconductor layer are in contact with each other, if a heat treatment process (e.g., 200° C. or more) is performed for some purpose after the formation of the source and drain electrodes, an oxidation-reduction reaction between the oxide semiconductor and Ti may occur in an area where the oxide semiconductor layer and the Ti layer are in contact with each other, thereby varying the TFT characteristics. Specifically, the threshold value significantly shifts on the negative side. It is believed that since Ti is more likely to have an oxidation-reduction reaction with an oxide semiconductor than other metals, oxygen deficiency is more likely to occur in the channel portion of the oxide semiconductor layer, thereby increasing the carrier concentration and deteriorating the off-leakage characteristic.

In contrast, in the present embodiment, since the TiN layer is provided between the Ti layer and the oxide semiconductor layer 5, it is possible to suppress the oxidation-reduction reaction between Ti and the oxide semiconductor. As a result, it is possible to reduce the oxygen deficiency occurring in the oxide semiconductor, and it is therefore possible to more reliably realize desirable TFT characteristics by suppressing the variation of the TFT threshold value deriving from the oxygen deficiency in the oxide semiconductor layer 5 (the channel region 5c).

Note that it has been known in the art that if the Ti layer of the source and drain electrodes and the oxide semiconductor layer are arranged to be in contact with each other in an oxide semiconductor TFT, a reaction layer is formed at the interface between the oxide semiconductor layer and the Ti layer, thereby reducing the contact resistance. Based on such a finding in the art, it was preferred to arrange the Ti layer and the oxide semiconductor layer to be in contact with each other, with no other layer, which does not form a reaction layer, interposed between these layers. Despite this conventional technical knowledge, embodiments of the present invention employ a structure where a reaction layer is unlikely formed. This suppresses the variation of the TFT threshold value. Note that the contact resistance can be reduced by other methods, such as by increasing the contact area, for example.

While Ti is used as the second metal herein, similar advantageous effects can be obtained when Mo is used instead. Specifically, a multilayer film of MoN/Mo/MoN may be used for the lower layers 7c, 9c. The MoN film of the lowermost layer may be arranged to be in contact with the oxide semiconductor layer 5. Moreover, Cu may be used, instead of Al, as the first metal contained in the main layers 7a, 9a.

The lower layers 7c, 9c of the source and drain electrodes may include any conductive layer other than those described above. Also in such a case, the advantageous effects described above can be obtained if a metal nitride layer (TiN or MoN layer) made of a nitride of the second metal is provided interposed between the metal layer made of the second metal (Ti or Mo layer) and the oxide semiconductor layer 5.

The oxide semiconductor TFT of the present embodiment may have a structure with a top gate structure, where the upper surface of the source and drain electrodes 7, 9 and the oxide semiconductor layer are in contact with each other. In such a case, the advantageous effects described above can be obtained if the upper layers 7b, 9b of the source and drain electrodes further include a metal nitride layer (herein, a TiN layer) on the opposite side of the main layers 7a, 9a from the metal layer (herein, a Ti layer), with the metal nitride layer being in contact with the oxide semiconductor layer 5. The oxide semiconductor TFT 103 may include no etch stop layer 6 (a channel-etched TFT).

Note that a method for manufacturing the oxide semiconductor TFT 102 of the present embodiment is similar to the method for manufacturing the oxide semiconductor TFT 101 described above with reference to FIGS. 3 to 5, except that the multilayer film forming the source and drain electrodes 7, 9 is different. Therefore, the manufacturing method will not be described below or illustrated in step-by-step diagrams.

### Third Embodiment

The oxide semiconductor TFT of the present embodiment is different from the oxide semiconductor TFT 101 (FIG. 1) described above in that the upper layer of the source and drain electrodes further includes another metal nitride layer between the metal layer and the first protective layer.

FIG. 7 is a cross-sectional view of an oxide semiconductor TFT 103 according to a third embodiment of the present invention.

In the oxide semiconductor TFT 103 of the present embodiment, the upper layers 7b, 9b of the source electrode and the drain electrode further include a TiN layer on the opposite side of the main layers 7a, 9a from the Ti layer. Thus, the upper layers 7b, 9b are a multilayer film including a TiN layer, a Ti layer and a TiN layer arranged in this order from the side of the main layers 7a, 9a. That is, it has a three-layer structure of TiN/Ti/TiN. In the example illustrated herein, the TiN layer of the uppermost layer of the upper layers 7b, 9b is in contact with the first protective layer 11. The first protective layer 11 is an oxide insulating film (herein, a silicon oxide film). Otherwise, the configuration is generally the same as the oxide semiconductor TFT 101.

In the present embodiment, as in the first embodiment, it is possible to suppress the mutual metal diffusion between the Ti layer and the main layers 7a, 9a, and it is possible to suppress the increase in the resistance of the source and drain electrodes 7, 9. As will be described below, it is also possible to obtain the advantageous effect of improving the adhesion between the source and drain electrodes 7, 9 and the first protective layer 11.

In a conventional oxide semiconductor TFT disclosed in Patent Document No. 2, etc., a multilayer film having a three-layer structure of Ti/Al/Ti, for example, is used as the source and drain electrodes, and the protective layer covering the TFT and the Ti layer are in contact with each other. An oxide insulating film such as a silicon oxide film, for example, is used as the protective layer. With such a configuration, if a heat treatment (e.g., 200° C. or more) is performed for some purpose after the formation of the protective layer, the surface of the Ti layer may be oxidized through an oxidation-reduction reaction between the Ti layer and the oxide insulating film. As a result, the adhesion between the source and drain electrodes and the protective layer may deteriorate and the protective layer may peel off, thereby lowering the production yield.

In contrast, in the present embodiment, since a TiN layer is provided between the Ti layer and the first protective layer 11, it is possible to suppress the oxidation-reduction reaction between Ti and the oxide semiconductor. As a result, it is possible to suppress the deterioration of the adhesion between the first protective layer and the source and drain electrodes and to increase the production yield.

While Ti is used as the second metal herein, similar advantageous effects can be obtained when Mo is used instead. Specifically, a multilayer film of MoN/Mo/MoN may be used as the upper layers 7b, 9b, and the MoN film of the uppermost layer may be arranged so as to be in contact with the first protective layer 11. Moreover, Cu may be used, instead of Al, as the first metal contained in the main layers 7a, 9a.

The lower layers 7c, 9c of the source and drain electrodes may include any conductive layer other than those described above. Also in such a case, the advantageous effects described above can be obtained if a metal nitride layer (TiN or MoN layer) made of a nitride of the second metal is provided interposed between the metal layer made of the second metal (Ti or Mo layer) and the first protective layer 11. Moreover, the oxide semiconductor TFT of the present embodiment may have a top gate structure. The oxide semiconductor TFT 103 may include no etch stop layer 6 (a channel-etched TFT).

Note that a method for manufacturing the oxide semiconductor TFT 103 of the present embodiment is similar to the method for manufacturing the oxide semiconductor TFT 101 described above with reference to FIGS. 3 to 5, except that the multilayer film forming the source and drain electrodes 7, 9 is different. Therefore, the manufacturing method will not be described below or illustrated in step-by-step diagrams.

### Fourth Embodiment

The semiconductor device of the present embodiment is different from the semiconductor device 201 (FIG. 2) described above in that the lower layer of the source and drain electrodes further includes a metal nitride layer (referred to also as a lower metal nitride surface layer) arranged between the lower metal layer and the oxide semiconductor layer, and the upper layer of the source and drain electrodes further includes a metal nitride layer (referred to also as an upper metal nitride surface layer) arranged between the upper metal layer and the first protective layer.

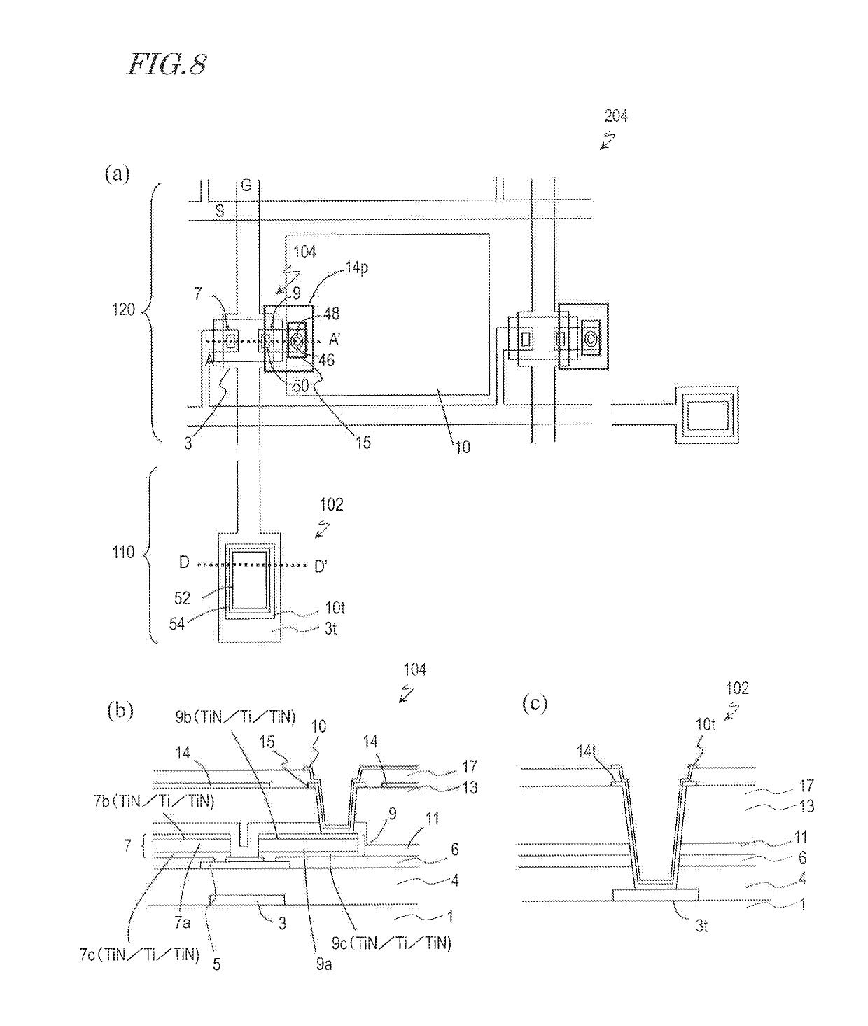

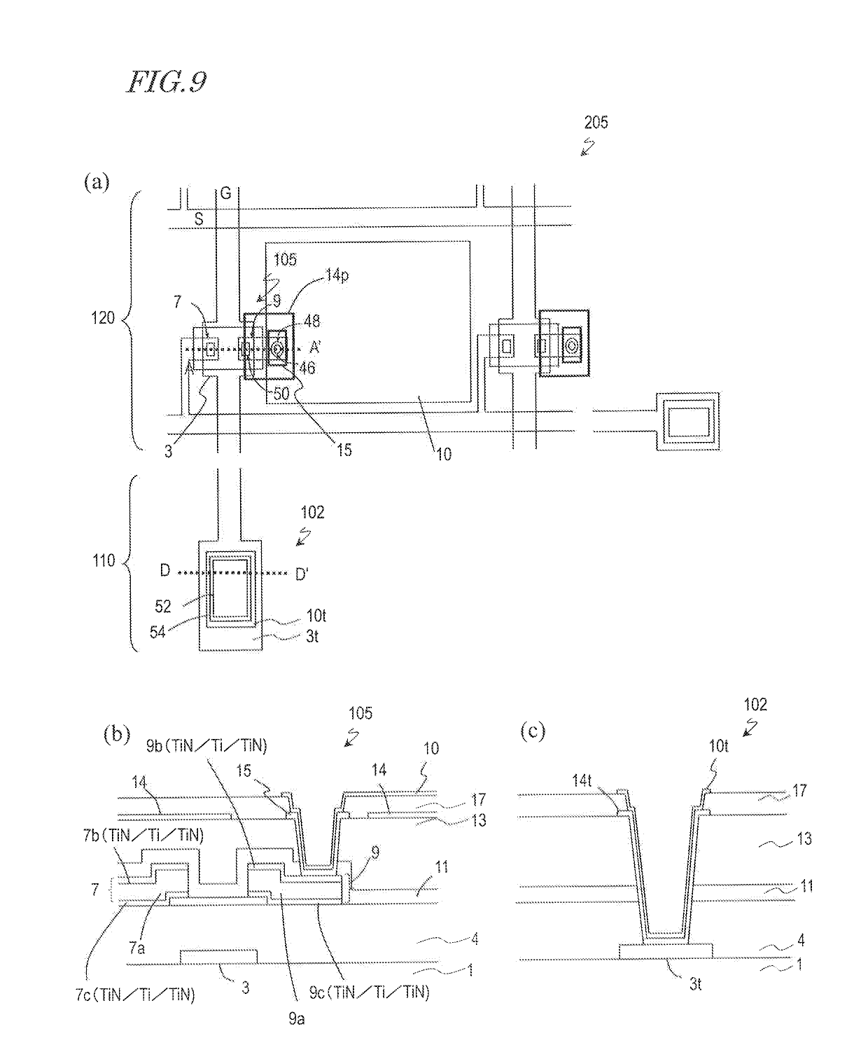

FIG. 8(a) is a plan view of a semiconductor device (active-matrix substrate) including an oxide semiconductor TFT 104 of the present embodiment. FIGS. 8(b) and 8(c) are cross-sectional views taken along line A-A′ and line D-D′, respectively, of FIG. 8(a). In FIG. 8, like elements to those of FIG. 2 are denoted by like reference numerals, and those elements will not be further described below.

In the oxide semiconductor TFT 104, the upper layers 7b, 9b and the lower layers 7c, 9c of the source and drain electrodes 7, 9 both have a three-layer structure of TiN/Ti/TiN. The TiN layer, which is the uppermost layer of the upper layers 7b, 9b, may be in contact with the first protective layer 11. The TiN layer, which is the lowermost layer of the lower layers 7c, 9c, may be in contact with the oxide semiconductor layer 5. An oxide insulating film (herein, a silicon oxide film) is formed as the first protective layer 11. Otherwise, the configuration is generally the same as the oxide semiconductor TFT 101.

In the present embodiment, as in the first embodiment, it is possible to suppress the mutual metal diffusion between the Ti layer and the main layers 7a, 9a, and it is possible to suppress the increase in the resistance of the source and drain electrodes. Since a TiN layer is provided between the oxide semiconductor layer 5 and the Ti layer, as in the second embodiment, it is possible to suppress the oxidation-reduction reaction between the oxide semiconductor and Ti, and it is possible to suppress the variation of the threshold value. Moreover, since a TiN layer is provided between the first protective layer 11 and the Ti layer, as in the third embodiment, it is possible to suppress the deterioration of the adhesion between the first protective layer 11 and the source and drain electrodes 7, 9.

While Ti is used as the second metal herein, similar advantageous effects can be obtained when Mo is used instead. Specifically, a multilayer film of MoN/Mo/MoN is used as the upper layers 7b, 9b and the lower layers 7c, 9c. The source and drain electrodes 7, 9 may include any conductive layer other than those described above. Cu may be used, instead of Al, as the first metal contained in the main layers 7a, 9a. Moreover, the oxide semiconductor TFT of the present embodiment may have a top gate structure. The oxide semiconductor TFT 104 may include no etch stop layer 6 (a channel-etched TFT).

Note that a method for manufacturing a semiconductor device 204 of the fourth embodiment is similar to the method for manufacturing the semiconductor device 201 described above with reference to FIGS. 3 to 5, except that the multilayer film forming the source and drain electrodes 7, 9 is different. Therefore, the manufacturing method will not be described below or illustrated in step-by-step diagrams.

### Fifth Embodiment

FIG. 9(a) is a plan view of a semiconductor device (active-matrix substrate) 205 including an oxide semiconductor TFT 105 of the present embodiment. FIGS. 9(b) and 9(c) are cross-sectional view taken along line A-A′ and line D-D′, respectively, of FIG. 9(a). In FIG. 9, like elements to those of FIG. 2 are denoted by like reference numerals, and those elements will not be further described below.

The oxide semiconductor TFT 105 is different from the oxide semiconductor TFTs 101 to 104 described above in that the oxide semiconductor TFT 105 is a channel-etched TFT (the etch stop layer 6 is absent).

In the illustrated example, the source and drain electrodes 7, 9 of the oxide semiconductor TFT 105 have the same structure as the source and drain electrodes 7, 9 of the oxide semiconductor TFT 104 of the fourth embodiment, for example. That is, the upper layers 7b, 9b and the lower layers 7c, 9c of the source and drain electrodes 7, 9 have a three-layer structure of TiN/Ti/TiN or MoN/Mo/MoN. Therefore, as in the fourth embodiment, it is possible to suppress the mutual metal diffusion between the Ti or Mo layer and the main layers 7a, 9a, and it is possible to suppress the increase in the resistance of the source and drain electrodes. It is also possible to suppress the oxidation-reduction reaction between the oxide semiconductor and Ti or Mo, and it is possible to suppress the variation of the threshold value. Moreover, it is possible to suppress the deterioration of the adhesion between the first protective layer 11 and the source and drain electrodes 7, 9. Note that in the present embodiment, as compared with a channel stop-type oxide semiconductor TFT (FIG. 2), the contact area between the source and drain electrodes 7, 9 and the oxide semiconductor layer 5 is larger, and it is therefore possible to realize more pronounced advantageous effects by suppressing the oxidation-reduction reaction between the oxide semiconductor and Ti or Mo.

<Method for Manufacturing Semiconductor Device 205>

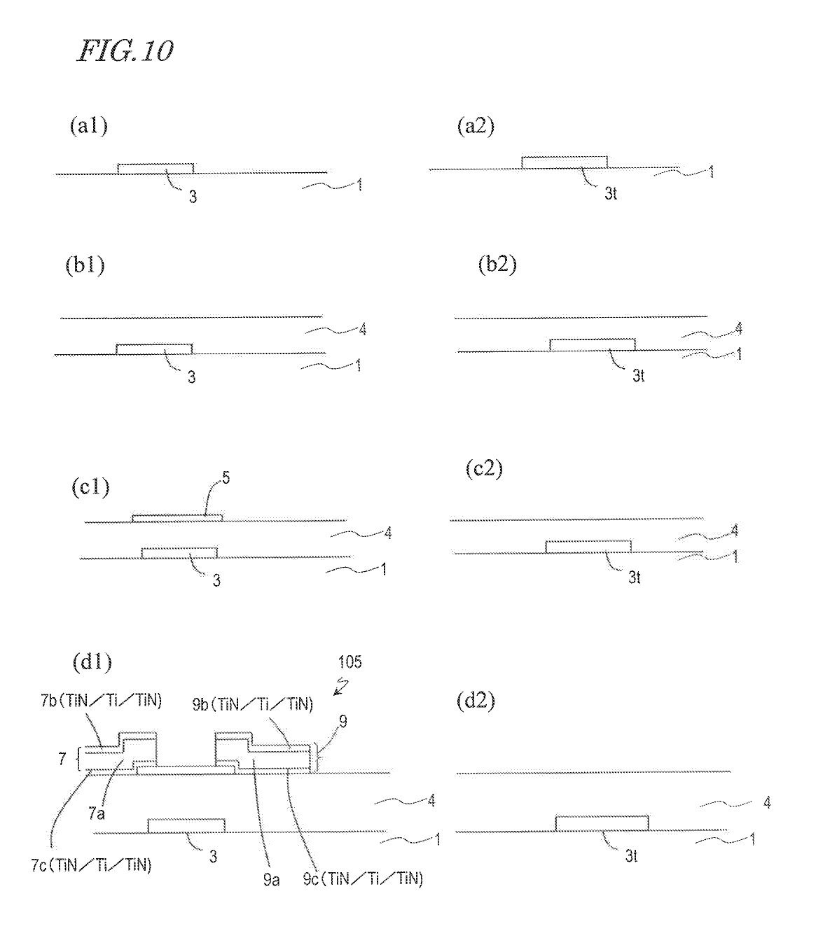

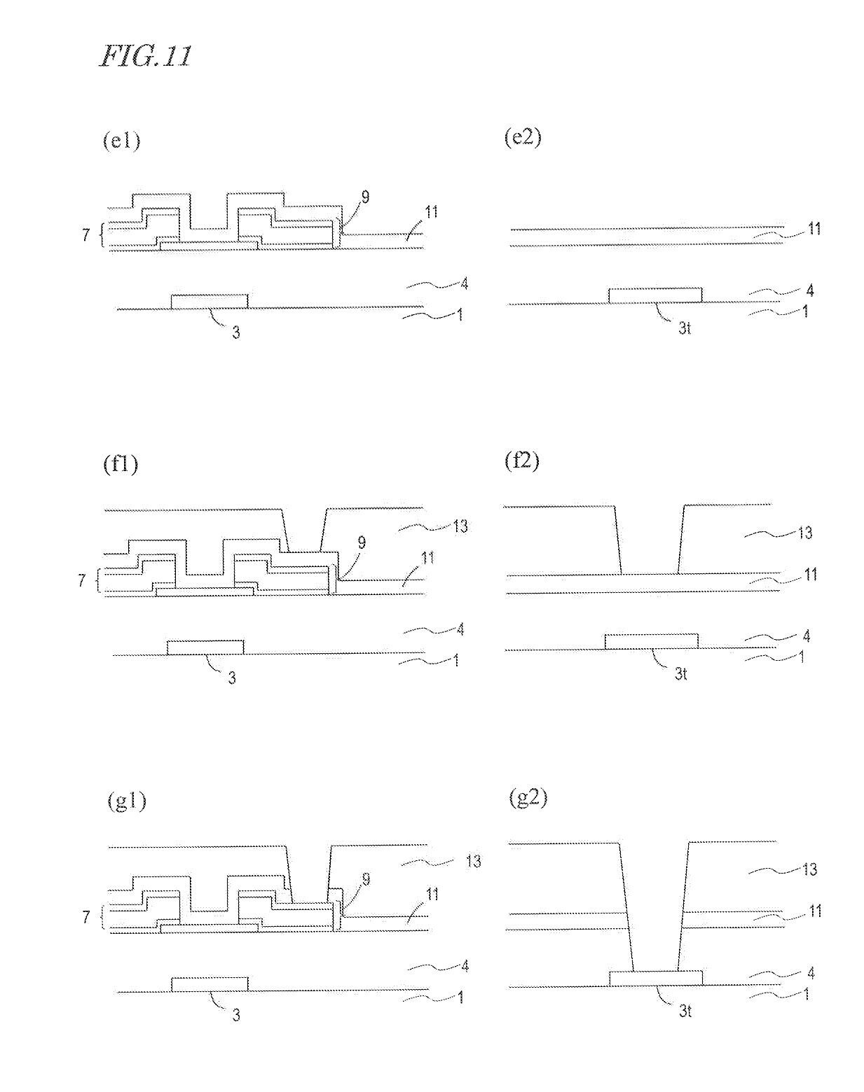

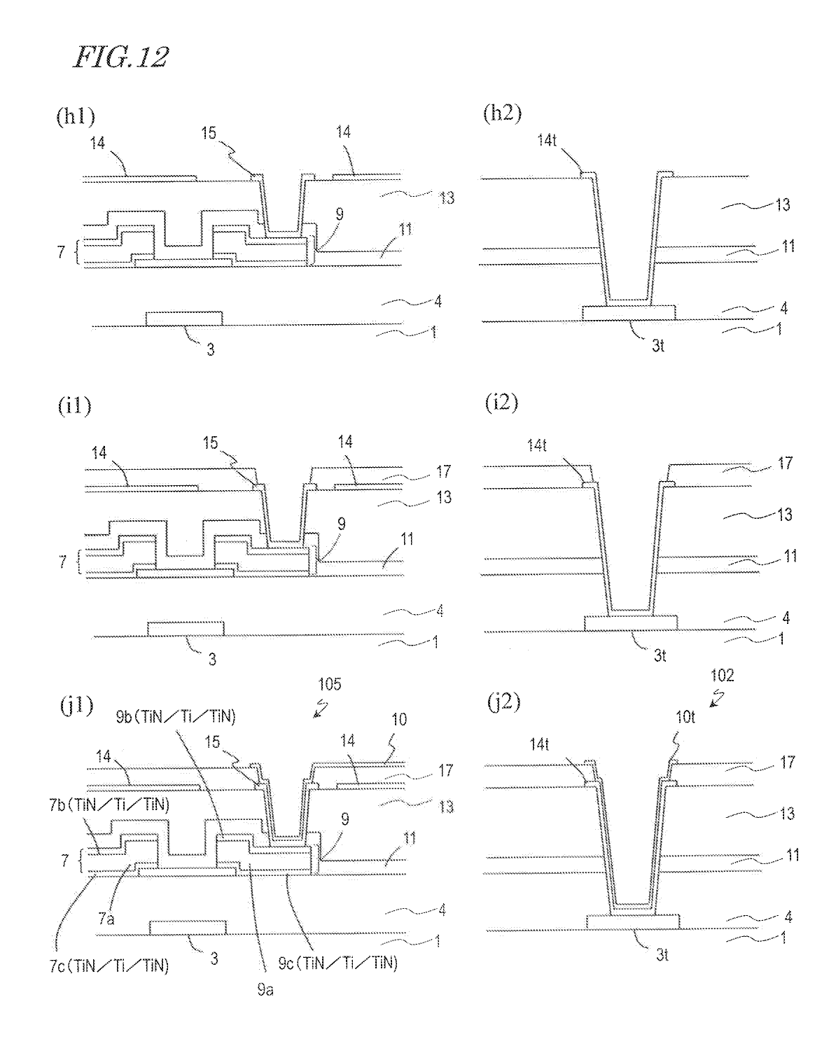

FIGS. 10 to 12 are cross-sectional views illustrating steps of an example method for manufacturing the semiconductor device 205, wherein (a1) to (j1) show the cross-sectional structure of the TFT formation region whereas (a2) to (j2) show that of the terminal portion formation region.

First, as shown in FIGS. 10(a1) to 10(c1) and 10(a2) to 10(c2), the gate electrode 3, the lower conductive layer 3t of the terminal portion 102, the gate insulating layer 4, and the oxide semiconductor layer 5 are formed on the substrate 1. These layers are formed by generally the same method as that described above with reference to FIGS. 3(a1) to 3(c1) and 3(a2) to 3(c2).

Next, although not shown, a source line metal film (thickness: 50 nm or more and 500 nm or less, for example) is formed by a sputtering method, or the like, for example, on the oxide semiconductor layer 5 and the gate insulating layer 4. Here, a multilayer film is formed as the source line metal film, including a TiN film, a Ti film, a TiN film, an Al film, a TiN film, a Ti film and a TiN film stacked in this order from the side of the oxide semiconductor layer 5. The thickness of each film of the multilayer film may be set within the thickness range set forth above in the first embodiment.

Next, the source line metal film is patterned, thereby forming the source line layer, including the source electrode 7, the drain electrode 9 and the source line, as shown in FIGS. 10(d1) and 10(d2). In the example illustrated herein, the source line layer is not formed in the terminal portion formation region. The source electrode 7 and the drain electrode 9 are each arranged so as to be in contact with the surface of the oxide semiconductor layer 5. Portions of the oxide semiconductor layer 5 that are in contact with the source electrode 7 and the drain electrode 9 are the source contact region and the drain contact region, respectively. A region that is located between the source contact region and the drain contact region and is in contact with no electrode becomes the channel region. Thus, the oxide semiconductor TFT 105 is obtained.

The subsequent steps shown in FIGS. 11(e1) to 12(j1) and FIGS. 11(e2) to 12(j2) are generally the same as those described above with reference to FIGS. 4(g1) to 6(l1) and FIGS. 4(g2) to 6(l2), and will not be further described below.

### INDUSTRIAL APPLICABILITY

Embodiments of the present invention are widely applicable to oxide semiconductor TFTs and various semiconductor devices having oxide semiconductor TFTs. For example, they are applicable to circuit substrates such as active-matrix substrates, display devices such as liquid crystal display devices, organic electroluminescent (EL) display devices and inorganic electroluminescent display devices, imaging devices such as image sensor devices, image input devices, fingerprint reader devices, and various electronic devices such as semiconductor memory devices.

### REFERENCE SIGNS LIST

1 substrate
3 gate electrode
4 gate insulating layer
5 oxide semiconductor layer (active layer)
5s source contact region
5d drain contact region
5c channel region
6 channel stop layer
7 source electrode
9 drain electrode
7a, 9a main layer
7b, 9b upper layer
7c, 9c lower layer
11, 13 protective layer
14 common electrode
15 connection layer
101, 102, 103, 104, 105 oxide semiconductor TFT
201, 204, 205 semiconductor device

1: A semiconductor device comprising a substrate, and a thin-film transistor supported on the substrate, wherein:
the thin-film transistor includes an oxide semiconductor layer, a gate electrode, a gate insulating layer formed between the gate electrode and the oxide semiconductor layer, and a source electrode and a drain electrode which are in contact with the oxide semiconductor layer;
each of the source electrode and the drain electrode includes:
a main layer including a first metal;
a lower layer arranged on the substrate side of the main layer, the lower layer including, in this order away from the main layer, a lower metal nitride layer made of a nitride of a second metal and a lower metal layer made of the second metal; and
an upper layer arranged on the opposite side of the main layer from the substrate, the upper layer including, in this order away from the main layer, an upper metal nitride layer made of a nitride of the second metal and an upper metal layer made of the second metal; and
the first metal is aluminum or copper, and the second metal is titanium or molybdenum.

2: The semiconductor device of claim 1, wherein the lower metal nitride layer is in contact with a lower surface of the main layer, and the upper metal nitride layer is in contact with an upper surface of the main layer.

3: The semiconductor device of claim 1, wherein one of the lower metal layer and the upper metal layer is in contact with the oxide semiconductor layer.

4: The semiconductor device of claim 1, wherein the upper layer or the lower layer of the source electrode and the drain electrode further includes another metal nitride layer made of a nitride of the second metal and arranged so as to be in contact with the oxide semiconductor layer.

5: The semiconductor device of claim 1, further comprising a first protective layer covering the thin-film transistor, the first protective layer being a silicon oxide film, wherein:
the upper layer of the source electrode and the drain electrode further includes another metal nitride layer made of a nitride of the second metal and arranged between the upper metal layer and the first protective layer; and
the other metal nitride layer is in contact with the first protective layer.

6: The semiconductor device of claim 1, further comprising a first protective layer covering the thin-film transistor, the first protective layer being a silicon oxide film, wherein:
the gate electrode is arranged between the substrate and the oxide semiconductor layer;
the lower layer of the source electrode and the drain electrode further includes a lower metal nitride surface layer made of a nitride of the second metal and arranged between the lower metal layer and the oxide semiconductor layer;
the upper layer of the source electrode and the drain electrode further includes an upper metal nitride surface layer made of a nitride of the second metal and arranged between the upper metal layer and the first protective layer; and
the lower metal nitride surface layer is in contact with the oxide semiconductor layer, and the upper metal nitride surface layer is in contact with the first protective layer.

7: The semiconductor device of claim 1, further comprising an etch stop layer covering a channel region of the oxide semiconductor layer.

8: The semiconductor device of claim 1, wherein the oxide semiconductor layer is a layer containing an In—Ga—Zn—O based oxide.

9: The semiconductor device of claim 8, wherein the oxide semiconductor layer is a layer containing a crystalline In—Ga—Zn—O based oxide.
